(19) United States
(12) Patent Application Publication
(10) Pub. No.: US 2008/0036036 A1
(43) Pub. Date: Feb. 14, 2008

(54) SEMICONDUCTOR DEVICE AND MANUFACTURING METHOD THEREOF

(75) Inventor: Shinichiro Wada, Fuchu (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 11/771,212

(22) Filed: Jun. 29, 2007

(30) Foreign Application Priority Data
Aug. 10, 2006 (JP) 2006-217716

(51) Int. Cl. H01L 29/00

(52) U.S. Cl. 257/536; 257/E29.001

(57) ABSTRACT

To easily obtain a resistance element with an adjustable resistance value, wherein the resistance value is within 1% or less of a desired design value, having a low parasitic capacitance and which permits a relatively large current to flow, in a semiconductor device wherein resistance elements are incorporated in a semiconductor substrate, the resistance values of the resistance elements can be adjusted within a fixed range, the first resistance element and second resistance element are disposed adjacent to each other within 500 μm, and both terminals of the second resistance element have two pads which are drawn out therefrom.

### CLAIM OF PRIORITY

The present application claims priority from Japanese application JP 2006-217716 filed on Aug. 10, 2006, the content of which is hereby incorporated by reference into this application.

### FIELD OF THE INVENTION

The present invention relates to a semiconductor device having resistance elements whereof the precision of the resistance values is 1% or less scatter with respect to a desired design value, and low parasitic capacitance.

### BACKGROUND OF THE INVENTION

FIG. 6 shows a termination resistor in an IC23 for active terminators according to the prior art. A buffer amplifier 25, and plural pairs of buffer amplifiers 26 and termination registers 24 are installed corresponding to each line of a bus line, the buffer amplifiers 25, 26 and termination resistors 24 all having identical structures. A terminal 27 is connected to the output of the buffer amplifier 25, the output potential (V1) can be measured, the termination register 24 is connected to the output of the buffer amplifier 26, and a terminal 28 which measures the current flowing into termination register, and a terminal 29 which measures a voltage (V2), are connected. Accordingly, the contact resistance of the probe and pad at the time of a probe test has no effect, and the resistance of termination register can be measured by the equation R=(V1−V2)/I. Next, in order to adjust the termination resistor 24 to the desired resistance, fuses 32a, 33a . . . 32n, 33n connected to resistance elements R12, R13 . . . Rn2, Rn3 in series are cut by a laser or the like to adjust the termination resistor 24 to a desired resistance value. For example, even if the ideal value of the termination resistor 24 is 50 Ω, and it varies within the range 49-51 Ω, a 2.5 KΩ resistance element for resistance adjustment is connected in parallel. If the measured resistance of the termination resistor 24 is 48 Ω, both fuses are cut to make 50 Ω, if the resistance value is 49 Ω, only one is cut, and if the resistance value is 50 Ω, neither is cut. This adjustment is performed for each termination resistor. Although the resistance of each termination resistor 24 can be adjusted with sufficient accuracy according to this technique, since the terminal 29 which measures voltage is connected to the termination resistor 24, there are the problems that parasitic capacitance increases and the rapidity of bus operation deteriorates.

FIG. 7 shows a prior art termination resistor in an IC50 for active terminators designed to avoid this problem. There is a buffer amplifier 25, dummy resistance 34, plural pairs of buffer amplifiers 26 and termination resistors 24 corresponding to each line of the bus lines, the buffer amplifiers 25, 26, dummy resistors 34 and termination resistors 24 all having identical constructions. The dummy resistor 34 connected to the output of the buffer amplifier 25 consists of a resistance element 40 and resistance elements 40a, 40b for resistance adjustment, the terminal 27 for voltage measurement, a terminal 39b, and a terminal 39a for current measurement being connected to the resistance element 40. Further, buffer amplifiers 26ab, 26ac, . . . , 26nb, 26nc are connected respectively to resistance elements 41a, 41b, . . . , 4na, 4nb for resistance adjustment which form a termination resistor via a control signal 36 and fuses 37, 38.

In order to adjust the resistance of termination resistor, the resistance of the resistance element 40 is first measured by equation R=(V1−V2)/I. Next, if the measured value is a desired value, all the termination resistors connected to the terminal 28 can be made ideal values by cutting all the fuses so that the output of the buffer amplifier connected to the resistance elements for adjusting resistance value is in the floating state. If the resistance value of the resistance element 40 is less than the ideal value, for example, if the actual measured value is 48 Ω compared to an ideal value of 50 Ω as in the previous example, the fuses 37, 38 are not cut, and the resistance values of the buffer amplifiers can be adjusted to the ideal values by putting the outputs of the buffer amplifiers 26ab, 26ac, . . . , 26nb, 26nc into the active state.

Here, since the resistance elements 40, 41, . . . , 4n and buffer amplifiers 25a, 26aa, . . . , 26na are formed in the same IC with the same construction, scatter is small as compared with another IC, so 41, . . . , 4n can be adjusted to the desired resistance.

JP-A 10-268993 shows the prior art examples of FIG. 6 and FIG. 7.

### SUMMARY OF THE INVENTION

In the technique of adjusting the resistance of the resistance element of this first prior art to an ideal value, to measure the resistance of a termination resistor, a voltage measurement terminal is provided. There was thus a problem that the parasitic capacitance of the termination resistor increased, and the rapidity of the bus operation deteriorated. In a second prior art that avoids this, plural resistance elements in the chip are adjusted together, using the fact that resistance elements having the same shape and structure in the same IC have a relatively small scatter. Accordingly, the voltage measurement terminal became unnecessary, and it was possible to manufacture a termination resistor having a low parasitic capacitance whereof the resistance could be adjusted. However, with this technique, since it is necessary to provide an amplifier connected to each resistance element, there is a disadvantage in that circuit size increases and chip size increases. Moreover, scatter in the resistance values of termination resistors having the same shape and construction formed in the same IC increases because they are formed further apart from each other. FIG. 8 shows the observed scatter in the resistance of resistance elements with the same shape and construction in the wafer. In this case, it is seen that if they are separated by 10 mm, there is a maximum scatter in the resistance values of about 0.5%. This is due to the fact that there is a scatter in the film thickness of the polysilicon layer forming the resistance element, or a distribution scatter in the treatment performed to activate impurities. The precision required of termination resistors to achieve high speed bus operation is increasing, and for a high speed bus exceeding 1 Gpbs, a precision of 1% or less is required. Even in resistances used for adjusting gain or offset in analog IC, high precision is required, and it is no longer possible to ignore the effect of scatter in one chip on resistance value precision.

It is therefore an object of the invention, which was conceived to resolve the above problems, to provide a resistance element whereof the precision of the resistance value is within 1% or less of the design value, and having a low parasitic capacitance.

The essential features of the invention disclosed within the scope of the present application may be simply described as follows.

The resistance element of the present invention has a resistance value which can be adjusted within a fixed range.

A first resistance element and corresponding second resistance element are disposed adjacent to each other within 500 μm in the same chip, and two terminals are drawn out respectively on both terminals of the second resistance element. Since voltage monitoring and current application can be performed separately by the aforesaid two terminals, the resistance value of the second resistance element can be measured with high precision.

The first and second resistance elements consist of resistance elements arranged in parallel so that the resistance can be adjusted, and fuses are connected to the resistance elements for resistance adjustment except the main resistance element. This fuse is cut based on the measured resistance, and is adjusted so that the second resistance element has a desired resistance. At this time, the same resistance as the second resistance element is obtained by cutting the fuse of the cut second resistance element and the fuse of the corresponding first resistance element. The first and second resistance elements have identical constructions, and since they are disposed close to each other, the scatter in their mutual resistance values is small. Moreover, since unnecessary parasitic capacitance is not added to the first resistance element, high-speed bus operation can be maintained.

In the invention, since there is no need for a resistance element which is a dummy resistance or connecting a buffer amplifier circuit to a resistance element for resistance adjustment as in the second prior art, increase of chip surface area can be suppressed.

In the invention, by making the length of each resistance element arranged in parallel the same, since the current density which flows into each resistance element can be made uniform, the reliability of the element when a large current is made to flow can be enhanced. Further, by giving more weight to the resistance value of each resistance element, compared to the case where more weight is not given to the resistance value, the range in which resistance value can be adjusted is increased, and the surface area of the resistance element can be made small.

A first aspect of the present invention is therefore (1), a semiconductor device on a semiconductor substrate comprising a first resistance element with an adjustable resistance value within a fixed range, a second resistance element having the same shape disposed adjacent thereto, these two resistance elements having two terminals, two pad terminals being drawn out from these two terminals, wherein said first resistance element and second resistance element have plural resistance elements with an adjustable resistance value connected in parallel with each other, the resistance element with an adjustable resistance value is itself a fuse which can be cut by a laser, and said plural resistance elements with an adjustable resistance value are arranged in a layout wherein they have the same length but different widths.

It is desirable that in (1), (2) the second resistance element is disposed adjacent to the first resistance element within a distance of 500 μm therefrom.

It is desirable that in (1), (3) the first resistance element has a resistance value which can be adjusted to within 1% or less scatter accuracy of a desired design value.

Another aspect of the first invention is (4) a semiconductor device on a semiconductor substrate comprising a first resistance element with an adjustable resistance value within a fixed range, a second resistance element having the same shape disposed adjacent thereto, these two resistance elements having two terminals, two pad terminals being drawn out from these two terminals, wherein said first resistance element and second resistance element have plural resistance elements with an adjustable resistance value connected in parallel with each other, the resistance element with an adjustable resistance value is connected in series with a fuse which can be cut by a laser, and said plural resistance elements with an adjustable resistance value are arranged in a layout wherein they have the same length but different widths.

It is desirable that in (4), (5) the second resistance element is disposed adjacent to said first resistance element within a distance of 500 μm therefrom.

It is desirable that in (4), the first resistance element has a resistance value which can be adjusted to within 1% or less scatter accuracy of a desired design value.

An aspect of a second invention is a method of manufacturing a semiconductor device, so device having plural resistance elements with an adjustable resistance value connected in parallel with each other, wherein the resistance element with an adjustable resistance value is itself a fuse which can be cut by a laser or is connected to a fuse which can be cut by a laser, the plural resistance elements with an adjustable resistance value are arranged in a layout wherein they have the same length but different widths, two resistance elements whereof the dimensions and shape can be considered to be identical are arranged adjacent to each other, and one resistance value is adjusted to match the measurement result of the other resistance element.

In (7), (8) the same dimensions and shape mean that in addition to an ideal completely identical construction, predetermined voltage output characteristics may be identical.

In (7), (9) one element is a dummy element, and the other element is a real resistance element connected to a circuit.

Another aspect of the second invention is (10) a method of manufacturing a semiconductor device having plural resistance elements with a resistance value which can be adjusted by trimming connected in parallel with each other, the resistance element with an adjustable resistance value is itself a fuse which can be cut by a laser, or is connected in series with fuses which can be cut by a laser, the resistance elements with an adjustable resistance value are arranged in a layout having the same length but different widths, two resistance elements whereof the dimensions and shape can be considered to be identical are arranged adjacent to each other, four terminals are drawn out from one element thereof as a dummy element, the resistance value is calculated by the four terminal method, and the other element is adjusted to match the resistance value of the dummy element so that it has a desired value.

The essential advantages of the invention disclosed within the scope of the present application may be simply described as follows.

A resistance element having a resistance value with a scatter of 1% or less of the desired design value, having a low parasitic capacitance and which can tolerate a relatively large current, can be formed while suppressing increase of chip size.

### BRIEF DESCRIPTION OF THE DRAWINGS

FIG. 1 is a schematic diagram of a semiconductor device into which the resistance element of the invention is incorporated;

FIG. 2 is a layout diagram (a) and cross-sectional view (b) of a resistance element according to a first embodiment of the invention;

FIG. 3 is a layout diagram (a) and cross-sectional view (b) of a resistance element according to another embodiment of the invention;

FIG. 4 is an example of a circuit diagram forming a resistance element according to one embodiment of the invention;

FIG. 5 is a diagram showing a flowchart for manufacturing a resistance element according to one embodiment of the invention;

FIG. 6 is a circuit diagram of an active terminator IC using a resistance element according to the prior art;

FIG. 7 is a circuit diagram of an active terminator IC using another resistance element according to the prior art; and

FIG. 8 is a diagram wherein scatter in the resistance value of a resistance element having an identical structure was observed in a wafer.

### DETAILED DESCRIPTION OF THE PREFERRED EMBODIMENTS

For the sake of convenience, the following description is divided into plural sections or embodiments, but unless specified otherwise, these are not mutually unrelated, and one thereof includes part or all of the modifications, details and additions of another.

Also, in the following embodiments, when numbers of elements (including numbers, figures, amounts and ranges) are mentioned, unless otherwise specified or when clearly limited in principle to a specific number, the invention is not limited to that specific number and may include a number which is larger or smaller.

Further, in the following embodiments, it will be understood that the component elements thereof (including elemental steps), unless otherwise specified or when considered to be clearly necessary, are not absolutely indispensable.

Likewise, in the following embodiments, when shape or positional relationships of component elements are mentioned, unless otherwise specified or when considered to be clearly unacceptable, they shall actually include close or approximate shapes or relationships. This is the same also for the aforesaid values and ranges.

Some embodiments of the invention will hereafter be described in detail based on the drawings.

### Embodiment 1

A resistance element in a semiconductor device according to this embodiment will now be described referring to the drawings.

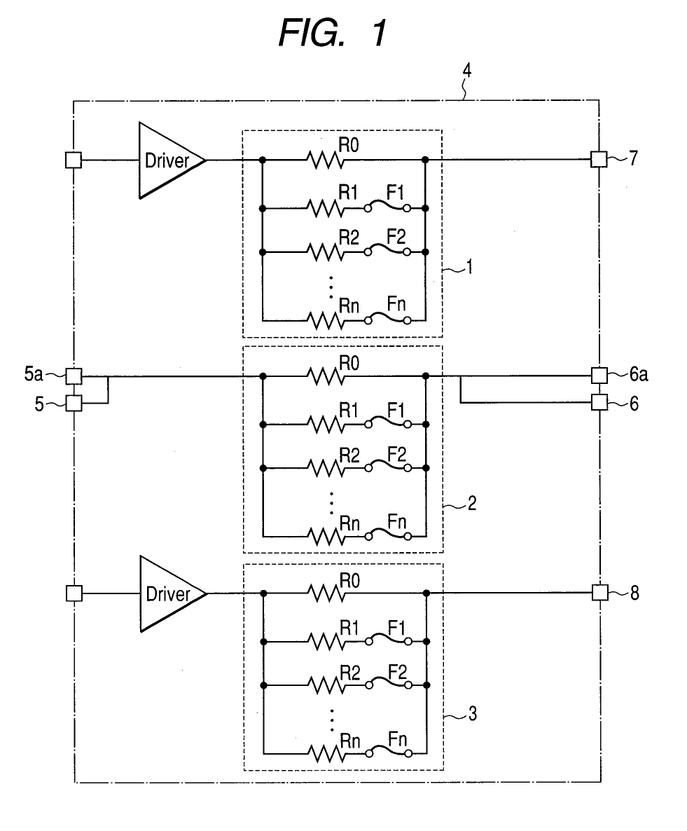

FIG. 1 is a schematic diagram of the resistance element in the semiconductor device (semiconductor integrated circuit device) of this invention. The circuit of FIG. 1 is a driver circuit whereof the input which is a minute signal of an ECL, the output is a 15V signal of about 2.5 Gpbs amplitude, and the circuit is connected to a DUT. A high precision 50 Ω termination resistor for impedance matching is connected to the driver circuit. A resistance element 2 which is a dummy resistance has two terminals respectively connected to pads 5, 6 for voltage monitoring and pads 5a, 6a for current application, and the resistance value thereof can be precisely measured without being affected by scatter in the contact resistance of the probe needle. Adjacent to the resistance element 2 which is a dummy resistance, termination resistors 1, 3 connected to the bus line are disposed adjacent to each other, one terminal being connected to the circuit, and one terminal being connected to pads 7, 8 connected to the bus line. The termination resistors 1, 3 which are paired with the dummy resistance element 2, comprise a main resistance R0 and resistance elements R1, R2, . . . , Rn for resistance adjustment connected in parallel therewith, and fuses F1, F2, . . . , Fn respectively connected in series with the resistance elements for resistance adjustment. In order to adjust the resistance of the termination resistors 1 and 3, the fuse to be cut is determined based on the measured resistance of the dummy resistor element 2. The fuse to be cut is connected to resistance elements for resistance adjustment of the same type in the termination resistors 1, 3 and dummy resistance element 2. After the fuse is cut, the resistance value of the dummy resistance element 2 is re-evaluated, and it is verified that it is the desired resistance value. The dummy resistance element 2 and termination resistors 1, 3 have identical structures and are disposed adjacent to each other, so the resistance value of the termination resistors can be estimated identical to that of the dummy resistance element. Due to this construction, the termination resistors 1 and 3 do not have pads for voltage measurement, so parasitic capacitance is not increased, and resistance can be measured and adjusted with high precision. In the diagrams, the resistance element was described as a termination resistor, but it may also be a resistance element for gain adjustment used in an analog IC, or a resistance element for offset cancellation.

### Embodiment 2

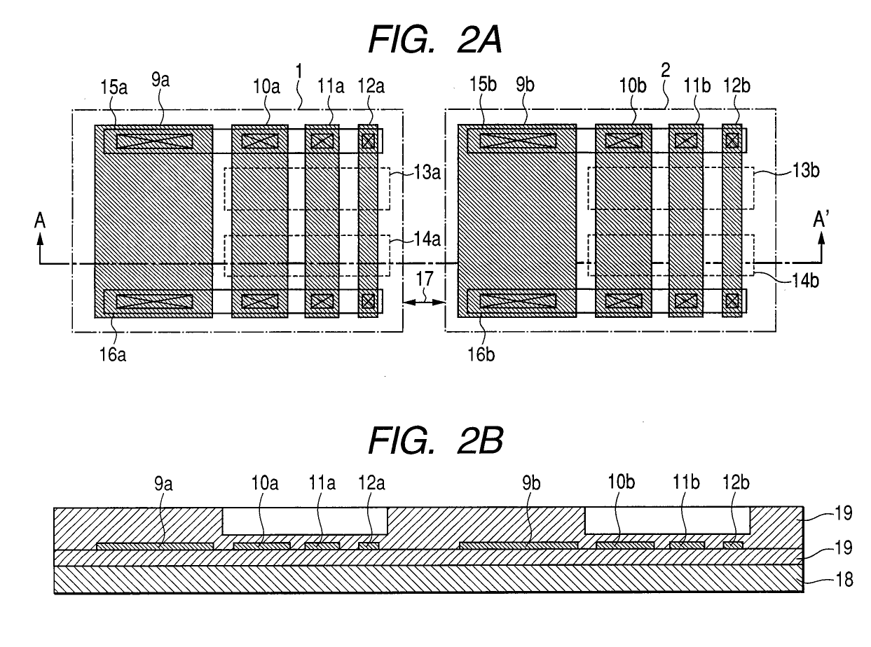

FIG. 2 shows a layout diagram and a cross-sectional structure of a resistance element in the semiconductor device of the invention. The resistance element 1 and the dummy resistor 2 have identical structures so that they form one pair, and the distance 17 between them is arranged to be within 500 μm. The resistance element is formed by a polySi layer or a metal layer such as TaN, TiN and SiCr. The resistance element comprises RO (9a, 9b) which is the main resistance and resistance elements 10, 11, 12 wherein the resistance itself functions as a fuse connected to interconnection layers 15, 16 in parallel, and whereof the lengths are identical to that of the main resistance RO. Due to this, since the current density flowing into the resistance element is essentially identical for each resistance, the reliability of the termination resistor connected to the driver circuit which requires a large current to flow, can be increased. Further, the width of the resistance elements 10, 11, 12 can be changed, and they are weighted. Due to this, compared to the case where the resistance value is not weighted, the range in which the resistance value can be adjusted is increased, and the surface area of the resistance element can be made small. Also, the insulation film of the upper parts 13, 14 is removed or the film thickness is reduced so that they can be cut by a laser. In this example, to increase laser cutting yield, two holes are provided.

### Embodiment 3

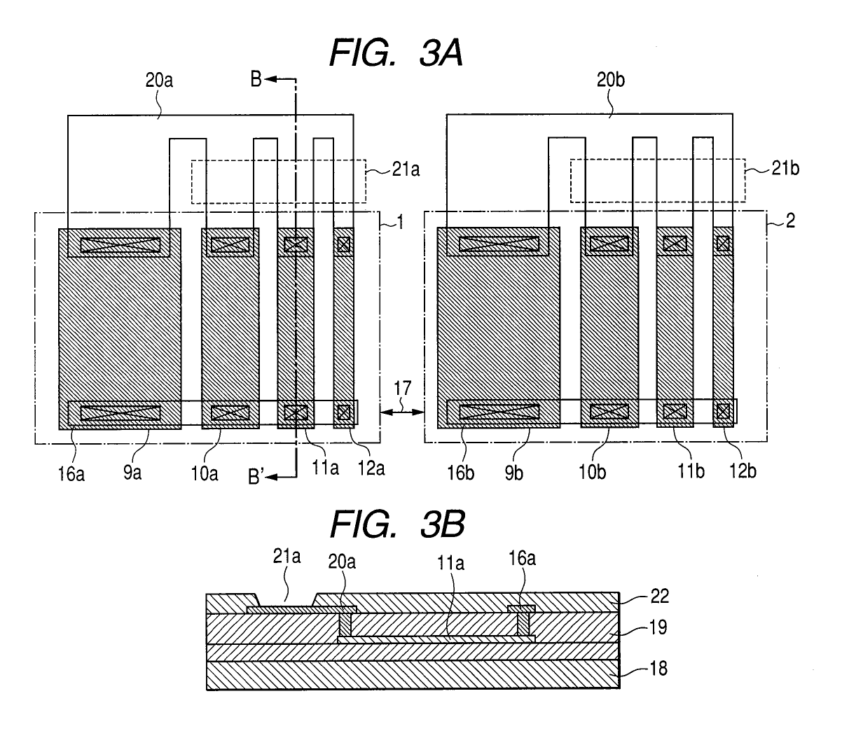

FIG. 3 shows a second example of a layout diagram and cross-sectional structure of the resistance element in the semiconductor device of the invention. Although the construction and composition of the resistance element are identical to those of FIG. 2, in FIG. 3, the fuses are formed by an interconnection layer 20 which connects the resistance elements. To increase the laser cutting yield, an insulation film 21 on the interconnection layer is removed or made thinner.

### Embodiment 4

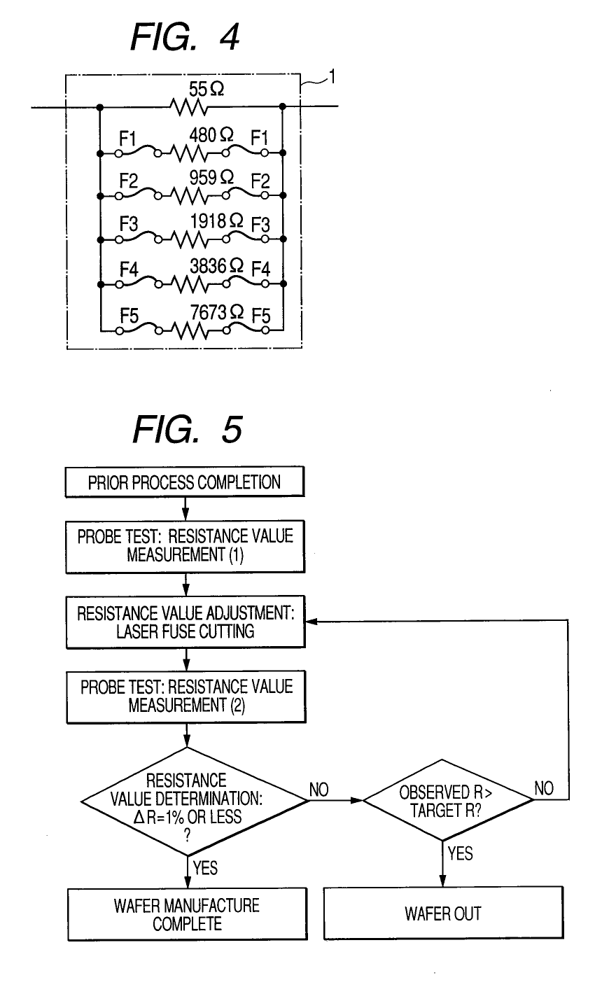

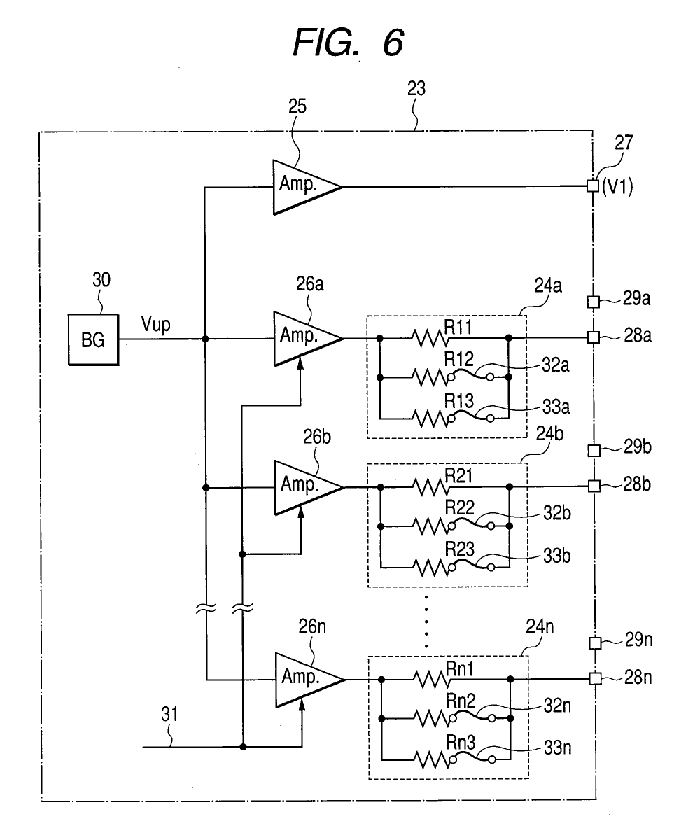

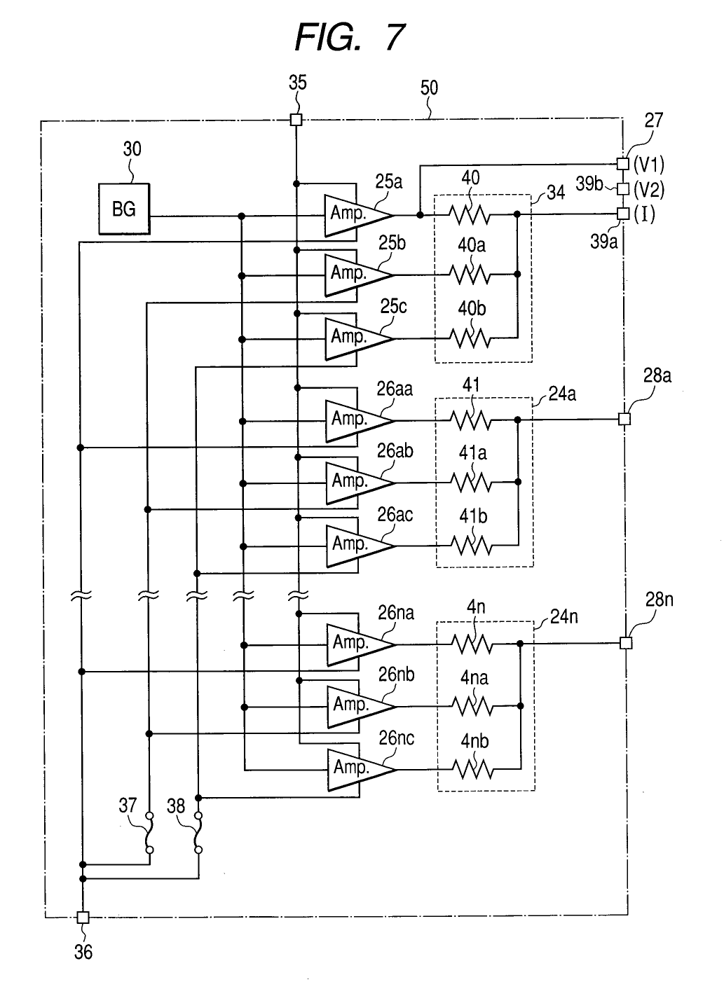

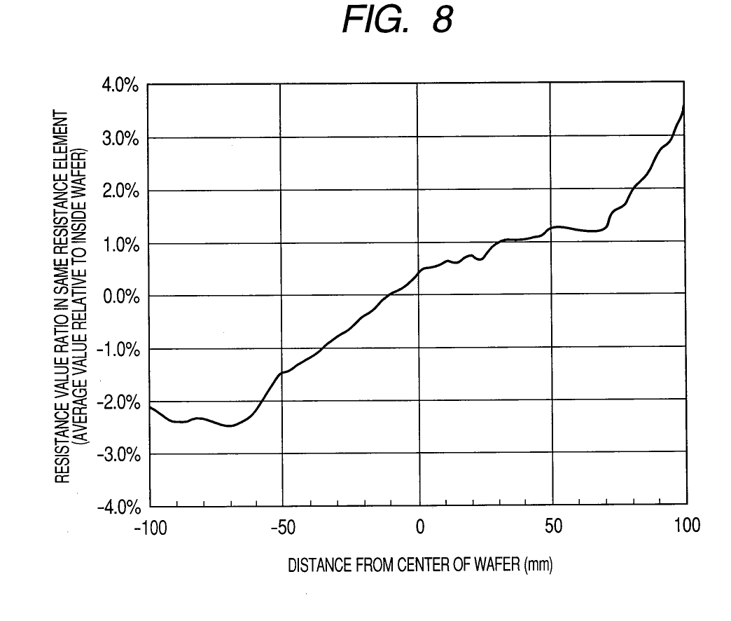

FIG. 4 is a circuit diagram wherein a weighting is given to the resistance elements for resistance adjustment R1, R2, . . . Rn described in FIGS. 2 and 3.

The resistance element 1 is designed to have a resistance value of 55 Ω when all the fuses are cut, and 45 Ω when none of the fuses are cut

In this case, there are 32 (25) ways of cutting the fuses, and the precision of the resistance value can be adjusted to within ±0.4%.

### Embodiment 5

FIG. 5 shows a manufacturing flow diagram for forming a resistance element in the semiconductor device of the invention. In a wafer which completed a previous process, the resistance of the dummy resistor is measured by a first probe test. Next, to adjust the resistance value to a desired value, a fuse is cut by the laser. Next, in a second probe test, the resistance value of the dummy resistor is measured, it is verified that the resistance value is within a desired resistance adjustment range, e.g., 1%, and wafer manufacture is completed. At this time, if the resistance value is finished to be larger than 1%, another fuse can be cut to adjust the resistance value. Further, the wafer can also be completed omitting the second probe test.

A resistance element with an adjustable resistance value, wherein the resistance value is within 1% or less of a desired design value, having a low parasitic capacitance and which permits a relatively large current to flow, can easily be obtained.

1. A semiconductor device on a semiconductor substrate comprising:
a first resistance element with an adjustable resistance value within a fixed range;
a second resistance element having the same shape disposed adjacent thereto, these two resistance elements having two terminals, and
two pad terminals being drawn out from these two terminals,
wherein said first resistance element and second resistance element have plural resistance elements with an adjustable resistance value connected in parallel with each other,
wherein the resistance element with an adjustable resistance value is itself a fuse which can be cut by a laser, and
wherein said plural resistance elements with an adjustable resistance value are arranged in a layout wherein they have the same length but different widths.

2. The semiconductor device according to claim 1, wherein said second resistance element is disposed adjacent to said first resistance element within a distance of 500 μm therefrom.

3. The semiconductor device according to claim 1, wherein said first resistance element has a resistance value which can be adjusted to within 1% or less scatter accuracy of a desired design value.

4. A semiconductor device on a semiconductor substrate comprising:
a first resistance element with an adjustable resistance value within a fixed range;
a second resistance element having the same shape disposed adjacent thereto, these two resistance elements having two terminals; and
two pad terminals being drawn out from these two terminals,
wherein said first resistance element and second resistance element have plural resistance elements with an adjustable resistance value connected in parallel with each other,
wherein the resistance element with an adjustable resistance value is connected in series with a fuse which can be cut by a laser, and
wherein said plural resistance elements with an adjustable resistance value are arranged in a layout wherein they have the same length but different widths.

5. The semiconductor device according to claim 4, wherein said second resistance element is disposed adjacent to said first resistance element within a distance of 500 μm therefrom.

6. The semiconductor device according to claim 4, wherein said first resistance element has a resistance value which can be adjusted to within 1% or less scatter accuracy of a desired design value.

7-10. (canceled)
